(19) United States
(12) Patent Application Publication
(10) Pub. No.: US 2008/0054478 A1
(43) Pub. Date: Mar. 6, 2008

(54) Semiconductor Device and Fabricating Method Thereof

(76) Inventor: CHEON MAN SHIM, Yeongdeungpo-gu (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/848,708

(22) Filed: Aug. 31, 2007

(30) Foreign Application Priority Data
Aug. 31, 2006 (KR) 10-2006-0083865

(51) Int. Cl. H01L 23/48; H01L 21/4763

(52) U.S. Cl. 257/773; 438/618; 257/E21.495; 257/E23.01

(57) ABSTRACT

A semiconductor device and fabricating method thereof are disclosed. An adhesive layer is provided between a metal layer and a dielectric barrier layer. A dielectric layer having a low dielectric constant is formed on the dielectric barrier layer.

### CROSS-REFERENCE TO RELATED APPLICATION

The present application claims the benefit under 35 U.S.C. §119 of Korean Patent Application No. 10-2006-0083865, filed Aug. 31, 2006, which is hereby incorporated by reference in its entirety.

### BACKGROUND

Semiconductor devices typically include a metal interconnection and a dielectric layer. Often, a dielectric barrier is used to inhibit the metal layer from diffusing into the dielectric layer. For example, a metal interconnection of a semiconductor device may include copper (Cu), and SiN may be used for a dielectric barrier that inhibits Cu from diffusing.

In addition, the dielectric barrier, employed to enhance the performance of a highly integrated device, typically has a low dielectric constant.

However, the use of a dielectric barrier often causes a peeling phenomenon during a pad process when a semiconductor is fabricated. This lowers the yield of a process and raises the costs. Also, an aluminum (Al) pad may not be able to be directly connected a Cu metal interconnection due to the peeling.

Thus, there exists a need in the art for an improved semiconductor device and fabricating method thereof that inhibits the peeling phenomenon.

### BRIEF SUMMARY

Embodiments of the present invention provide a semiconductor device and a fabricating method thereof. Adhesive properties between a metal layer and a dielectric barrier layer can be enhanced, thereby improving the reliability and characteristics of the device.

In an embodiment, a semiconductor device includes a metal layer, an adhesive layer on the metal layer, a dielectric barrier layer on the adhesive layer, and a dielectric layer on the dielectric barrier layer.

A metal layer is formed on a semiconductor substrate, and an adhesive layer is formed on the metal layer. A dielectric barrier layer is then formed on the adhesive layer, and a dielectric layer is formed on the dielectric barrier layer.

### BRIEF DESCRIPTION OF THE DRAWINGS

FIG. 1 is a cross-sectional view showing a semiconductor device according to an embodiment of the present invention.

FIG. 2 is a flowchart representing a method of manufacturing a semiconductor device according to an embodiment of the present invention.

### DETAILED DESCRIPTION

When the terms “on” or “over” are used herein, when referring to layers, regions, patterns, or structures, it is understood that the layer, region, pattern or structure can be directly on another layer or structure, or intervening layers, regions, patterns, or structures may also be present. When the terms “under” or “below” are used herein, when referring to layers, regions, patterns, or structures, it is understood that the layer, region, pattern or structure can be directly under the other layer or structure, or intervening layers, regions, patterns, or structures may also be present.

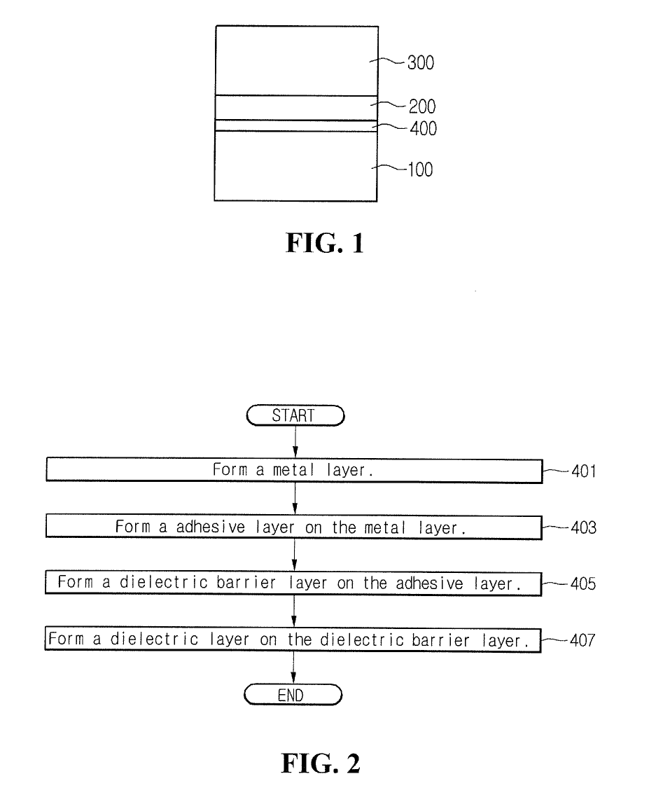

Referring to FIG. 1, an Inter Layer Dielectric (ILD) layer according to an embodiment of the present invention can include a metal layer 100, an adhesive layer 400, a dielectric barrier layer 200, and a dielectric layer 300.

The metal layer 100 can be used for forming an interconnection. For example, the metal layer 100 can include copper (Cu) to be able to form an interconnection of low resistance. The adhesive layer 400 can serve as a buffer layer to enhance the adhesive properties between the metal layer 100 and the dielectric barrier layer 200.

In an embodiment, the dielectric barrier layer 200 can include SiCN, SiCON, or both.

In order to enhance the adhesive properties between the dielectric barrier layer 200 and the metal layer 100, the adhesive layer 400 can include SiN. In an embodiment, the adhesive layer 400 can be formed to a thickness of about 10 Å to about 300 Å.

The dielectric layer 300 can have a low dielectric constant (k) and can be formed on the dielectric barrier layer 200. In an embodiment, the dielectric layer 300 can include any material having a dielectric constant (k) of less than 3. The dielectric layer 300 can be formed by any appropriate method known in the art, for example, Plasma Enhanced Chemical Vapor Deposition (PECVD) or a spin casting process. The dielectric layer can be formed using SiOC:H, porous SiOC:H, porous SiO₂, or any other appropriate material known in the art.

In a semiconductor device according to embodiments of the present invention, adhesive properties between the metal layer 100 and the dielectric barrier layer 200 can be enhanced by the adhesive layer 400. Thus, the peeling phenomenon between the dielectric barrier layer 200 and the metal layer 100 can be inhibited from occurring, leading to a semiconductor device with improved characteristics.

A method of manufacturing a semiconductor device according to an embodiment of the present invention is represented in a flowchart in FIG. 2.

Referring to FIG. 2, a metal layer 100 can be formed (401).

The metal layer 100 can be for forming a metal interconnection. For example, the metal layer 100 can include Cu to be able to form an interconnection of low resistance.

Then, an adhesive layer 400 can be formed on the metal layer 100 (403).

The adhesive layer 400 can serve as a buffer layer in order to enhance the adhesive properties between the metal layer 100 and a dielectric barrier layer 200.

Then, the dielectric barrier layer 200 can be formed on the adhesive layer 400 (405).

In an embodiment, the dielectric barrier layer 200 can include SiCN, SiCON, or both. In order to enhance the adhesive properties between the dielectric barrier layer 200 and the metal layer 100, the adhesive layer 400 can include SiN. In an embodiment, the adhesive layer 400 can be formed to a thickness of about 10 Å to about 300 Å. Since SiN has a superior adhesive property relative to Cu, the peeling phenomenon is prevented from occurring during the subsequent bonding process. The SiN can have a dielectric constant (k) between about 6 and about 8.

The dielectric layer 300 can be formed on the dielectric barrier layer 200 (407).

The dielectric layer 300 can be formed using any material having a dielectric constant (k) of less than 3. The dielectric layer 300 can be formed by PECVD, spin casting, or any other appropriate method known in the art. The dielectric layer 300 can be formed using any appropriate material known in the art, for example, SiOC:H, porous SiOC:H, or porous SiO₂.

In a semiconductor device according to embodiments of the present invention, the adhesive properties between the metal layer 100 and the dielectric barrier layer 200 can be enhanced by the adhesive layer 400. Thus, the peeling phenomenon between the dielectric barrier layer 200 and the metal layer 100 can be inhibited.

The reliability of a device can be improved by inhibiting the peeling phenomenon during a pad process.

Since the peeling phenomenon is inhibited, an aluminum (Al) can be directly connected with a Cu interconnection. As a result, according to embodiments of the present invention, the number of net dies in a wafer is increased, thereby increasing the efficiency of the wafer.

In the semiconductor device and the method of manufacturing the same according to the present invention, the adhesive properties between a metal layer for an interconnection and the dielectric barrier layer is improved, thereby enhancing the reliability and effectiveness of the device.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A semiconductor device, comprising:
a metal layer on a semiconductor substrate;
an adhesive layer on the metal layer;
a dielectric barrier layer on the adhesive layer; and
a dielectric layer on the dielectric barrier layer.

2. The semiconductor device according to claim 1, wherein the metal layer comprises Cu.

3. The semiconductor device according to claim 1, wherein the adhesive layer has a thickness of about 10 Å to about 300 Å.

4. The semiconductor device according to claim 1, wherein the dielectric barrier layer comprises at least one material selected from the group consisting of SiCN and SiCON.

5. The semiconductor device according to claim 1, wherein the dielectric layer comprises a material having a dielectric constant (k) of less than 3.

6. The semiconductor device according to claim 1, wherein the dielectric layer comprises at least one material selected from the group consisting of SiOC:H, porous SiOC:H and porous SiO₂.

7. The semiconductor device according to claim 1, wherein the adhesive layer comprises SiN.

8. The semiconductor device according to claim 7, wherein the SiN has a dielectric constant of from about 6 to about 8.

9. A method of manufacturing a semiconductor device, comprising:
forming a metal layer on a semiconductor substrate;
forming an adhesive layer on the metal layer;
forming a dielectric barrier layer on the adhesive layer; and
forming a dielectric layer on the dielectric barrier layer.

10. The method according to claim 9, wherein the metal layer comprises Cu.

11. The method according to claim 9, wherein the adhesive layer has a thickness of about 10 Å to about 300 Å.

12. The method according to claim 9, wherein the dielectric barrier layer comprises at least one material selected from the group consisting of SiCN and SiCON.

13. The method according to claim 9, wherein the dielectric layer comprises a material having a dielectric constant (k) of less than 3.

14. The method according to claim 9, wherein forming the dielectric layer comprises performing PECVD or a spin casting process, and wherein forming the dielectric layer comprises using at least one material selected from the group consisting of SiOC:H, porous SiOC:H, and porous SiO₂.

15. The method according to claim 9, wherein the dielectric layer comprises at least one material selected from the group consisting of SiOC:H, porous SiOC:H and porous SiO₂.

16. The method according to claim 9, wherein the adhesive layer comprises SiN.

17. The method according to claim 16, wherein the SiN has a dielectric constant of about 6 to about 8.
